(19) United States
(12) Patent Application Publication
(10) Pub. No.: US 2026/0333958 A1
(43) Pub. Date: Oct. 22, 2026

(54) DISPLAY PANEL AND DISPLAY DEVICE

(71) Applicant: Shanghai Tianma Microelectronics Co., Ltd., Shanghai (CN)

(72) Inventors: Qijun Yao, Shanghai (CN); Yaodong Wu, Shanghai (CN)

(73) Assignee: Shanghai Tianma Microelectronics Co., Ltd., Shanghai (CN)

(21) Appl. No.: 19/695,553

(22) Filed: Jun. 2, 2026

(30) Foreign Application Priority Data
Dec. 30, 2025 (CN) 202512035958.5

(51) Int. Cl. H10H 20/853; H10H 20/855

(52) U.S. Cl. CPC H10H 20/853; H10H 20/855

(57) ABSTRACT

Provided are a display panel and a display device. The display panel includes a driving substrate, light-emitting devices, encapsulation structures, and lens structures. The light-emitting devices are electrically connected to one side of the driving substrate. The encapsulation structure covers the light-emitting surfaces of the light-emitting devices. The encapsulation structure includes side surfaces and a bottom surface, and the included angle between the side surface and the bottom surface is an obtuse angle. The lens structure is located on one side of the encapsulation structure facing away from the light-emitting device. The lens structure includes a first lens, and the first lens includes a first surface facing the encapsulation structure and protruding toward the light-emitting device. Along the thickness direction of the display panel, the light-emitting device, the first lens, and the encapsulation structure at least partially overlap.

### CROSS-REFERENCE TO RELATED APPLICATION(S)

This application claims priority to Chinese Patent Application No. 202512035958.5 filed with the China National Intellectual Property Administration (CNIPA) on Dec. 30, 2025, the disclosure of which is incorporated herein by reference in its entirety.

### TECHNICAL FIELD

Embodiments of the present disclosure relate to the field of display technologies and, in particular, to a display panel and a display device.

### BACKGROUND

Currently, display panels are being applied in an increasingly wide range of fields, and the performance requirements for the display panels are no longer limited to high brightness and clarity at a normal viewing angle. The light emission performance at an oblique viewing angle has gradually become a key evaluation indicator. This trend is particularly prominent in special applications such as head-up displays (HUDs), where strict constraints are typically imposed on the structural space and the light emission angle, creating an urgent need for a display panel maintaining excellent visual performance even at an oblique viewing angle.

However, under existing technical conditions, display panels suitable for such scenarios still exhibit deficiencies in actual oblique light emission performance, such as brightness attenuation and color shift, finally affecting the visual experience of the user.

### SUMMARY

Based on this, the present disclosure provides a display panel and a display device in which an encapsulation structure on the light-emitting side of a light-emitting device collects the leaked light at a large viewing angle and a lens structure converges light for emission at an oblique viewing angle, thereby increasing the brightness of the display panel at an oblique viewing angle, mitigating color shift, and improving the display effect of the display panel at an oblique viewing angle.

In a first aspect, an embodiment of the present disclosure provides a display panel. The display panel includes a driving substrate, a light-emitting device, an encapsulation structure, and lens structures.

The light-emitting device is electrically connected to one side of the driving substrate.

The encapsulation structure covers the light-emitting surface of the light-emitting device, the encapsulation structure includes side surfaces and a bottom surface, and the included angle between the side surface and the bottom surface is an obtuse angle.

The lens structure is located on one side of the encapsulation structure facing away from the light-emitting device, the lens structure includes a first lens, and the first lens includes a first surface facing the encapsulation structure and protruding toward the light-emitting device.

Along a thickness direction of the display panel, the light-emitting device, the first lens, and the encapsulation structure at least partially overlap.

In a second aspect, an embodiment of the present disclosure further provides a display device. The display device includes the display panel provided in the first aspect.

### BRIEF DESCRIPTION OF DRAWINGS

FIG. 1 is a schematic view of a display panel in the related art.

FIG. 2 is a sectional view of the display panel in FIG. 1 taken along aa′.

FIG. 3 is a schematic view of a display panel according to an embodiment of the present application.

FIG. 4 is a sectional view of the display panel in FIG. 3 taken along AA′.

FIG. 5 is a schematic view of another display panel according to an embodiment of the present application.

FIG. 6 is a schematic view of another display panel according to an embodiment of the present application.

FIG. 7 is a sectional view of the display panel in FIG. 6 taken along BB′.

FIG. 8 is another sectional view of the display panel in FIG. 6 taken along BB′.

FIG. 9 is a schematic view of another display panel according to an embodiment of the present application.

FIG. 10 is a sectional view of the display panel in FIG. 9 taken along CC′.

FIG. 11 is a schematic view of another display panel according to an embodiment of the present application.

FIG. 12 is a sectional view of the display panel in FIG. 11 taken along DD'.

FIG. 13 is another sectional view of the display panel in FIG. 11 taken along DD'.

FIG. 14 is a brightness test view of a light-emitting device at different viewing angles according to an embodiment of the present application.

FIG. 15 is a schematic view of another display panel according to an embodiment of the present application.

FIG. 16 is a schematic view of another display panel according to an embodiment of the present application.

FIG. 17 is a schematic view of another display panel according to an embodiment of the present application.

FIG. 18 is a sectional view of the display panel in FIG. 15 taken along EE′.

FIG. 19 is a structural view of a display device according to an embodiment of the present disclosure.

FIG. 20 is a schematic view of the optical path structure of a display device applied to an HUD according to an embodiment of the present disclosure.

### DETAILED DESCRIPTION

The present application is further described in detail below in conjunction with the drawings and embodiments. It is to be understood that the embodiments described herein are intended to illustrate the present application and not to limit the present application. Additionally, it is to be noted that for ease of description, only part, not all, of structures related to the present application are illustrated in the drawings. It is apparent for those skilled in the art that various modifications and variations can be made in the present application without departing from the spirit or scope of the present application. Accordingly, the present application is intended to cover modifications and variations of the present application that fall within the scope of the appended claims (the claimed technical solutions) and their equivalents. It is to be noted that embodiments of the present application, if not in collision, may be combined with one another.

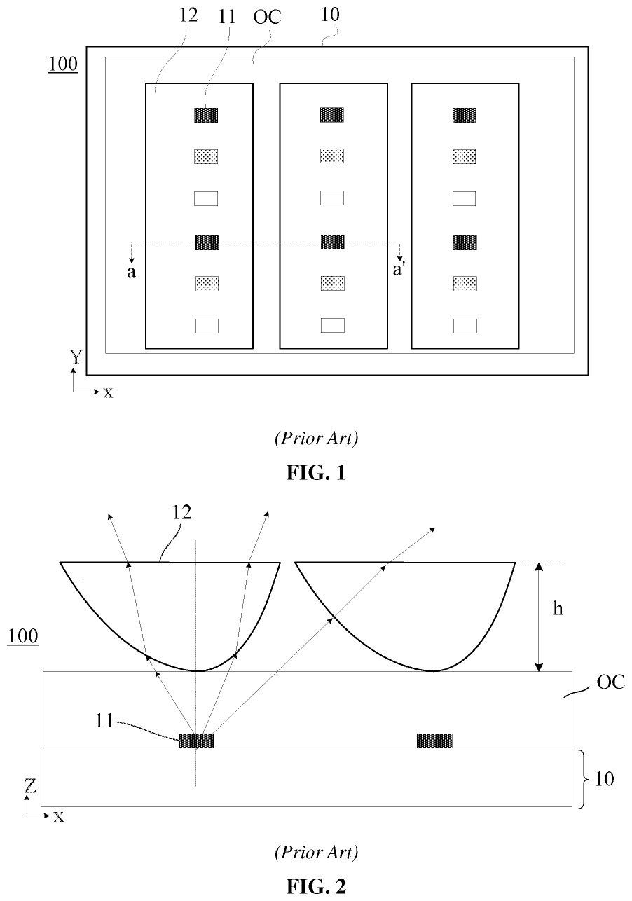

FIG. 1 is a schematic view of a display panel in the related art. FIG. 2 is a sectional view of the display panel in FIG. 1 taken along aa′. Referring to FIGS. 1 and 2, in the related art, a display panel 100 with oblique-angle emission is provided. The display panel 100 includes a driving substrate 10, light-emitting devices 11, an encapsulation layer OC, and lens structures 12. For the display panel 100 that requires oblique-angle light emission, the imprinted-formed lens structure 12 is typically fabricated on the light-emitting side of the light-emitting device 11. Generally, the larger the dimension of the lens structure 12 is and the farther away the lens structure 12 is from the light-emitting device 11, the more significant the light converging effect is. However, an excessively large lens structure 12 significantly increases the overall thickness h, easily leading to a decrease in the precision of the imprinting process and weakening the light converging performance. This contradiction is particularly prominent in application scenarios such as HUDs, which have strict requirements on the structural space and the light emission angle. Such applications often require the light source to have specific oblique light emission characteristics, requiring a thicker lens to regulate the optical path. However, excessively increasing the lens thickness h not only reduces the optical fabrication precision but also weakens the light converging performance, adversely affecting the visual performance of the display panel, such as brightness attenuation and color shift, finally affecting the visual experience of the user.

The normal viewing angle refers to an observation angle perpendicular to the light-emitting surface of the light-emitting device, that is, 0 degrees. It may also be understood as viewing the display panel 100 along the z-direction in FIG. 1. The oblique viewing angle refers to an observation angle that is not perpendicular to the light-emitting surface of the light-emitting device, that is, viewing from the side.

Based on the preceding technical problems, the inventor has proposed a display panel and a display device. The display panel includes a driving substrate, light-emitting devices, encapsulation structures, and lens structures. The light-emitting devices are electrically connected to one side of the driving substrate. The encapsulation structure covers the light-emitting surfaces of the light-emitting devices. The encapsulation structure includes side surfaces and a bottom surface, and the included angle between the side surface and the bottom surface is an obtuse angle. The lens structure is located on one side of the encapsulation structure facing away from the light-emitting device. The lens structure includes a first lens, and the first lens includes a first surface facing the encapsulation structure and protruding toward the light-emitting device. Along the thickness direction of the display panel, the light-emitting device, the first lens, and the encapsulation structure at least partially overlap.

Through the preceding technical solutions in the present application, the encapsulation structure on the light-emitting side of the light-emitting device is divided into multiple independent modules, leaked light at a large viewing angle is collected through the side surface of the encapsulation structure and directed to the lens structure, and the lens structure converges the light for emission at an oblique viewing angle, thereby increasing the brightness of the display panel at an oblique viewing angle, mitigating color shift, and improving the display effect of the display panel at an oblique viewing angle.

The preceding is the core idea of the present disclosure. Technical solutions in embodiments of the present disclosure are described clearly and completely in conjunction with the drawings in the embodiments of the present disclosure. Based on the embodiments of the present disclosure, all other embodiments obtained by those of ordinary skill in the art are within the scope of the present disclosure on the premise that no creative work is done.

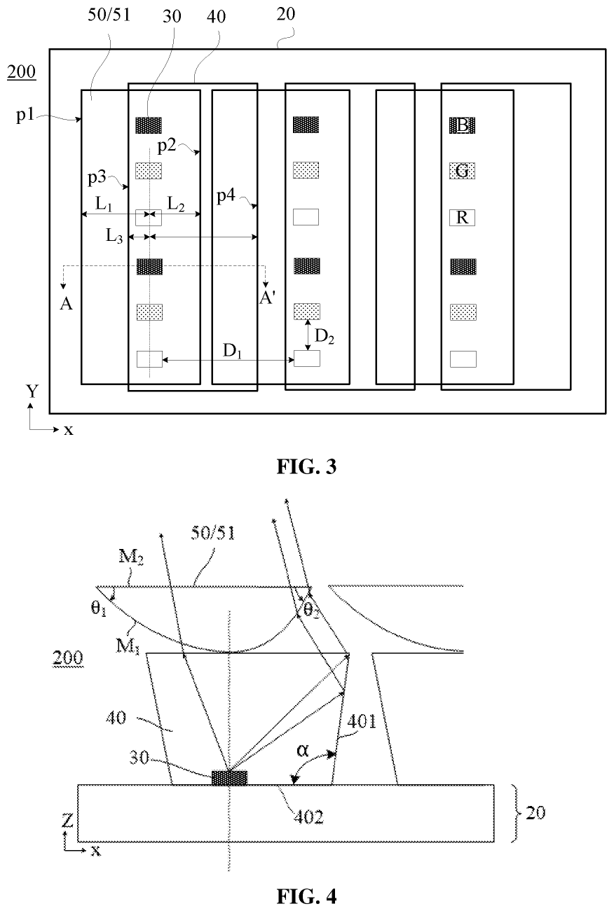

FIG. 3 is a schematic view of a display panel according to an embodiment of the present application. FIG. 4 is a sectional view of the display panel in FIG. 3 taken along AA′. Referring to FIGS. 3 and 4, a display panel 200 provided in the present application includes a driving substrate 20, a light-emitting device 30, an encapsulation structure 40, and a lens structure.

In the embodiment of the present application, the display panel 200 includes, but is not limited to, a light-emitting diode (LED) display panel, a micro light-emitting diode (Micro LED) display panel, a mini light-emitting diode (Mini LED) display panel, or the like. The embodiment of the present disclosure does not limit the type of display panel.

The light-emitting device is electrically connected to one side of the driving substrate 20. The types of light-emitting devices 30 include, but are not limited to, LED, Micro LED, Mini LED, and the like, which are not limited in the embodiment of the present disclosure.

The driving substrate 20 includes multiple pixel circuits (not shown in the figure). The pixel circuits are connected to the light-emitting devices 30 and are used for providing drive voltages to the light-emitting devices 30 to control brightness. The pixel circuit may be a circuit structure such as 2T1C, 4T1C, 7T1C, 7T2C, 8T1C, 8T2C, or the like. The pixel circuit includes multiple thin-film transistors (TFTs), storage capacitors, metal wires, and other film structures (not shown in the drawings of the embodiments of the present disclosure), which may be clearly understood by those skilled in the art, and the details are not repeated here.

In the embodiment of the present application, the encapsulation structure 40 covers the light-emitting surface of the light-emitting device 30. The light-emitting surface refers to the physical surface from which the light-emitting device 30 emits light. The encapsulation structure 40 includes side surfaces 401 and a bottom surface 402, and the included angle α between the side surface 401 and the bottom surface 402 is an obtuse angle. The materials of the encapsulation structure 40 include, but are not limited to, the optically clear adhesive (OCA) and the optically clear resin (OCR). For example, the included angle α between the side surface 401 and the bottom surface 402 of the encapsulation structure 40 may also be referred to as a reverse chamfer.

The lens structure 50 is located on one side of the encapsulation structure 40 facing away from the light-emitting device 30. The material of the lens structure 50 may be a transparent material with a high refractive index and the lens structure 50 can converge the light emitted from the light-emitting device 30. The lens structure 50 includes a first lens 51. The first lens 51 includes a first surface M₁ facing the encapsulation structure 40 and protruding toward the light-emitting device 30. The first surface M₁ can converge and deflect the light emitted from the light-emitting device 30 to the viewing angle. Referring to FIG. 4, along the thickness direction Z of the display panel 200, the light-emitting device 30, the encapsulation structure 40, and the first lens 51 at least partially overlap. In this manner, the encapsulation structure 40 and the first lens 51 can converge the light emitted from the light-emitting device 30 and then make the light emitted at an oblique angle. The viewing angle refers to a viewing angle from which the user views the display panel. In the HUD application, the viewing angle is usually an oblique viewing angle.

Compared with the related art, in the embodiment of the present application, the encapsulation structure 40 is divided into multiple independent module structures, and the side surface of the encapsulation structure 40 collects part of the light for emission at an oblique viewing angle. Further considering that the leaked light of the light-emitting device 30 usually has a larger angle, the included angle α between the side surface 401 and the bottom surface 402 of the encapsulation structure 40 is set to an obtuse angle. This design facilitates the reflection of the light at a large viewing angle from the side surface 401 toward the first surface M₁, and the part of light is then converged by the first lens 51 and emitted at an oblique viewing angle so that effective collection of the light at a large viewing angle and the propagation direction adjustment can be achieved, thereby improving the utilization efficiency of the light emitted at an oblique viewing angle, enhancing the overall optical performance, increasing the brightness of the display panel, mitigating color shift, and ultimately improving the visual experience of the user.

Based on the preceding embodiments, referring to FIG. 3, the first lens 51 includes a first edge p₁ and a second edge p₂, and the first edge p₁ and the second edge p₂ are arranged along a first direction X and extend along a second direction Y. The first direction X and the second direction Y intersect and are both parallel to the plane where the driving substrate 20 is located. In the embodiment of the present application, the first lens 51 may be a strip-shaped lens structure extending along the Y direction. The encapsulation structure 40 corresponding to the first lens 51 includes a third edge p₃ and a fourth edge p₄, and the third edge p₃ and the fourth edge p₄ are arranged along the first direction X and extend along the second direction Y. Along the first direction X, the distance L₁ between the first edge p₁ and the light-emitting device 30 is greater than the distance L₂ between the second edge p₂ and the light-emitting device 30, and the distance L₃ between the third edge p₃ and the light-emitting device 30 is less than the distance L₄ between the fourth edge p₄ and the light-emitting device 30.

Along the X direction in FIG. 1, the distance L₁ refers to the minimum distance between the first edge p₁ of the first lens 51 and the center of the light-emitting surface of the light-emitting device 30, the distance L₂ refers to the maximum distance between the second edge p₂ of the first lens 51 and the center of the light-emitting surface of the light-emitting device 30, and L₁>L₂. The distance L₃ refers to the maximum distance between the third edge p₃ of the encapsulation structure 40 and the center of the light-emitting surface of the light-emitting device 30, the distance L₄ refers to the minimum distance between the fourth edge p₄ of the encapsulation structure 40 and the center of the light-emitting surface of the light-emitting device 30, and L₃<L₄. This design can ensure that the center of the first lens 51 corresponding to the light-emitting device 30, the center of the encapsulation structure 40, and the center of the light-emitting surface of the light-emitting device 30 are offset from one another. Moreover, on the premise that the light-emitting device 30, the first lens 51, and the encapsulation structure 40 at least partially overlap, oblique angle polarization control along the X direction can be performed on the light emitted by the light-emitting device 30.

Based on the preceding embodiments, referring to FIG. 4, the first lens 51 further includes a second surface M₂ facing away from the encapsulation structure 40. Along the first direction X, the included angles between the first surface M₁ and the second surface M₂ include a first base angle θ₁ and a second base angle θ₂. The first base angle θ₁ and the second base angle θ₂ are different, that is, θ₁≠θ₂. In the embodiment of the present application, the first lens 51 may be a non-axisymmetric cylindrical prism. By setting the two opposite base angles of the first lens 51 to be unequal, asymmetric regulation of the emitting optical path can be achieved, thereby generating a polarization effect along a specific direction.

In an embodiment of the present application, with continued reference to FIG. 3, the display panel 200 includes multiple light-emitting devices 30 arranged in an array, and the distance D₁ between two adjacent light-emitting devices 30 arranged in the first direction X is greater than the distance D₂ between two adjacent light-emitting devices 30 arranged in the second direction Y. The orthographic projection of the first lens 51 on the driving substrate 20 covers multiple light-emitting devices 30 arranged along the second direction Y.

In the embodiment of the present application, the light-emitting devices 30 of the display panel 200 may be arranged in various manners. In the present application, based on the distribution characteristics of the distance between the light-emitting devices 30, the layout of the first lenses 51 is reasonably configured such that the light converging performance can be optimized while ensuring the optical fabrication precision. In one or more embodiments, the first lens 51 is configured to extend along the Y direction and cover multiple light-emitting devices 30. In this design, the optical structure is closely integrated with the device arrangement so that the fabrication difficulty can be reduced, the feasibility of the process can be improved, and the directional deflection of the light emitted by multiple light-emitting devices 30 arranged along the Y direction can be effectively achieved, thereby enabling light to be emitted uniformly in the same direction and significantly improving the uniformity of the light emission angles and the light regulation effect.

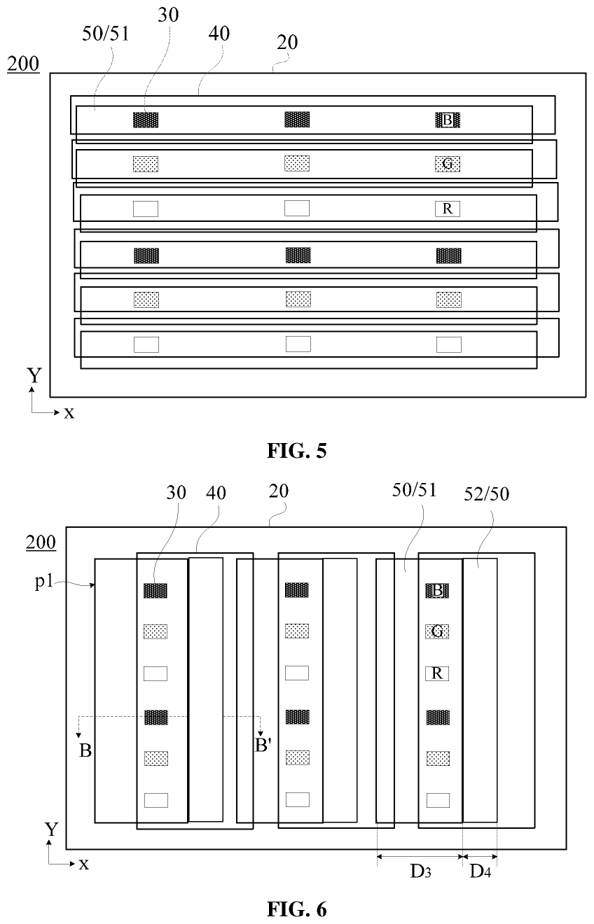

FIG. 5 is a schematic view of another display panel according to an embodiment of the present application. In another embodiment of the present application, referring to FIG. 5, in the present application, the orthographic projection of the first lens 51 on the driving substrate 20 covers the multiple light-emitting devices 30 arranged along the first direction X. This structural design enables the directional deflection of the light emitted by multiple light-emitting devices 30 arranged along the X direction, thereby enabling light to be emitted uniformly in the same direction and improving the uniformity of the light emission angles and the light regulation effect.

It is to be noted that the array arrangement of the light-emitting devices 30 shown in FIG. 3 is used as an example for an illustrative description in the embodiment of the present application, and the structure of the lens structure 50 of the present application is not limited to this.

Based on the preceding embodiments, with continued reference to FIG. 3, along the first direction X, the light emission colors of the multiple light-emitting devices 30 are the same. For example, along the first direction X, the first row consists entirely of blue light-emitting devices B, the second row consists entirely of green light-emitting devices G, and the third row consists entirely of red light-emitting devices R. Along the second direction Y, at least two of the multiple light-emitting devices 30 covered by the orthogonal projection of the same first lens 51 on the substrate 20 emit different colors.

In one or more embodiments, based on the existing arrangement of the light-emitting devices 30 in the display panel 200, the first lens 51 is configured to extend along the Y direction and cover multiple light-emitting devices 30 of different colors. This arrangement allows light of different colors to pass through the same first lens 51 and be deflected and emitted in the same direction, which is conducive to improving the mixing effect among different colors of light and effectively solving problems such as color shift in the display.

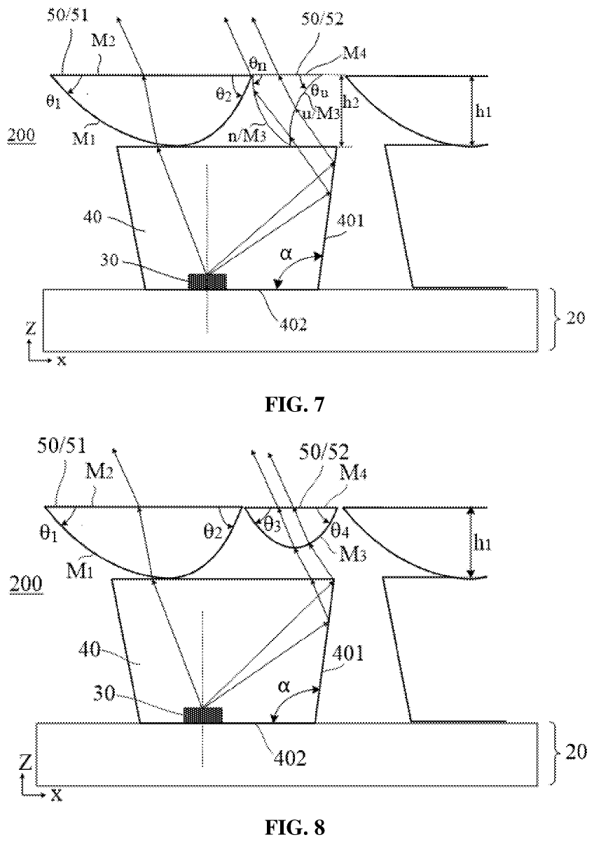

FIG. 6 is a schematic view of another display panel according to an embodiment of the present application. FIG. 7 is a sectional view of the display panel in FIG. 6 taken along BB′. FIG. 8 is another sectional view of the display panel in FIG. 6 taken along BB′. Based on the preceding embodiments, referring to FIGS. 6 to 8, the lens structure 50 further includes a second lens 52, and the second lens 52 is located between two adjacent first lenses 51 and at least partially surrounds the first lens 51. Along the thickness direction Z of the display panel 200, the second lens 52 and the encapsulation structure 40 at least partially overlap.

Compared with the related art, in the present application, the encapsulation structure 40 is divided into multiple independent module structures, and the side surface of the encapsulation structure 40 collects part of light at a large viewing angle for light emission at an oblique viewing angle, thereby increasing the brightness at an oblique viewing angle. After the brightness is increased, in the present application, the thickness h1 of the first lens 51 may be reduced, that is, h1<h, the second lens 52 is provided between adjacent first lenses 51, and the second lens 52 further collects the light at a large viewing angle for light emission at an oblique viewing angle, thereby balancing the optical loss caused by the thinning. The second lens 52 and the first lens 51 may have the same or different optical parameters. In one or more embodiments, the side surface 401 of the encapsulation structure 40 reflects the leaked light at a large viewing angle, and the second lens 52 converges the light, thereby enhancing the brightness of the light deflection and emission, improving the utilization rate of the light at a large viewing angle, and ultimately improving the overall optical energy utilization rate.

It is to be emphasized that the thickness h1 of the first lens 51 is reduced in the present application, which is conducive to improving the optical fabrication precision and light converging performance of the first lens 51.

Based on the preceding embodiments, referring to FIG. 7, the second lens 52 includes a third surface M₃ facing the encapsulation structure 40. The third surface M₃ includes a convex surface n and a concave surface u connected to each other. The convex surface n is located on one side of the concave surface u facing the first lens 51 and protrudes toward the first lens 51. The concave surface u is recessed toward the included angle α between the side surface 401 and the bottom surface 402 of the encapsulation structure 40. The convex surface n and the concave surface u form a continuous and smooth third surface M₃.

In the embodiment of the present application, the second lens 52 further includes a fourth surface M₄ facing away from the encapsulation structure 40. Along the first direction X, the included angle between the convex surface n and the fourth surface M₄ is a third base angle θₙ, and the included angle between the concave surface u and the fourth surface M₄ is a fourth base angle θᵤ. According to the geometric relationship, θₙ>θᵤ. The concave surface u of the second lens 52 can deflect the reflected light at a smaller angle for light emission at an oblique viewing angle, while the convex surface n can deflect the reflected light at a larger angle for light emission at an oblique viewing angle. In this design, the second lens 52 can at least collect part of the emitted light at a large angle as a compensation for the loss caused by the thinning of the first lens 51, thereby improving the optical fabrication precision and the light converging performance and enhancing the light deflection and emission effect.

Based on the preceding embodiments, referring to FIG. 7, along the thickness direction Z of the display panel 200, the thickness h₁ of the first lens 51 and the thickness h₂ of the second lens 52 are the same, that is, h₁ =h₂.

Along the thickness direction Z of the display panel 200, the thickness h₁ refers to the thickness of the first lens 51 from the first surface M₁ to the second surface M₂, and the thickness h₂ refers to the thickness of the second lens 52 from the third surface M₃ to the fourth surface M₄. In the embodiment of the present application, the thicknesses of the first lens 51 and the second lens 52 are limited as described above, which is conducive to achieving the uniformity of the precision of the imprinting process, enabling precise control of the deflection of the optical path, and achieving effective convergence of light from different viewing angles.

Based on the preceding embodiments, referring to FIG. 8, the second lens 52 includes the third surface M₃ facing the encapsulation structure 40 and the fourth surface M₄ facing away from the encapsulation structure 40, and the third surface M₃ protrudes toward the light-emitting device 30. Along the first direction X, the included angles between the third surface M₃ and the fourth surface M₄ include a third base angle θ₃ and a fourth base angle θ₄. The third base angle θ₃ and the fourth base angle θ₄ are different. The first direction X is parallel to the plane where the driving substrate 20 is located. In the embodiment of the present application, the second lens 52 and the first lens 51 may be two non-axisymmetric cylindrical prisms, and the first surface M₁ of the first lens 51 and/or the third surface M₃ of the second lens 52 may both be parabolic. For example, the second lens 52 with a smaller dimension may be directly imprinted in a gap region between two adjacent first lenses 51. The thicknesses of the two lenses may be different. The first lens 51 converges and deflects the light from the light-emitting device 30 at a small viewing angle, while the second lens 52 converges and deflects the light reflected from the side surface 401 of the encapsulation structure 40 at a large viewing angle.

Based on the preceding embodiments, with continued reference to FIG. 8, the first lens 51 further includes the second surface M₂ facing away from the encapsulation structure 40. Along the first direction X, the included angles between the first surface M₁ and the second surface M₂ include the first base angle θ₁ and the second base angle θ₂. Along the X direction, the first base angle θ₁, the second base angle θ₂, the third base angle θ₃, and the fourth base angle θ₄ are arranged in sequence. In the embodiment of the present application, the third base angle θ₃ of the second lens 52 is less than or equal to the first base angle θ₁ of the first lens 51, that is, θ₃≤θ₁. The fourth base angle θ₄ of the second lens 52 is less than or equal to the second base angle θ₂ of the first lens 51, that is, θ₄≤θ₂. In the example of the present application, through the angle settings, the width of the second lens 52 in the X direction can be reduced, which is also conducive to making the second lens 52 and the first lens 51 deflect light in the same direction.

The included angle (the third base angle θ₃) between the third surface M₃ and the fourth surface M₄ is the included angle (the third base angle θₙ) between the convex surface n and the fourth surface M₄, and the included angle (the fourth base angle θ₄) between the third surface M₃ and the fourth surface M₄ is the included angle (the fourth base angle θᵤ) between the concave surface u and the fourth surface M₄.

Based on the preceding embodiments, referring to FIG. 8, the first base angle θ₁ of the first lens 51 may be less than or equal to the second base angle θ₂, that is, θ₁≤θ₂, and the third base angle θ₃ of the second lens 52 may be less than or equal to the fourth base angle θ₄, that is, θ₃≤θ₄. For example, the first lens 51 is scaled down proportionally and set as the second lens 52, and θ₁, θ₂, θ₃, and θ₄ are reasonably adjusted such that the emitted light is uniformly deflected to the left side in the figure.

In FIG. 8, in the XZ plane, the cross-sectional profiles of the first surface M₁ of the first lens 51 and the third surface M₃ of the second lens 52 are asymmetric curves. For example, both the first surface M₁ and the third surface M₃ may be parabolic surfaces, such as elliptical parabolic surfaces.

Based on the preceding embodiments, with continued reference to FIG. 6, along the first direction X, the width D₃ of the first lens 51 is greater than the width D₂ of the second lens 52. The first direction X is parallel to the plane where the driving substrate 20 is located. In the embodiment of the present application, the second lens 52 with a smaller dimension is provided in the gap region between two adjacent first lenses 51, and the second lens 52 converges the leaked light reflected from the side surface 401 of the encapsulation structure 40 at a large viewing angle, thereby increasing brightness and mitigating color shift.

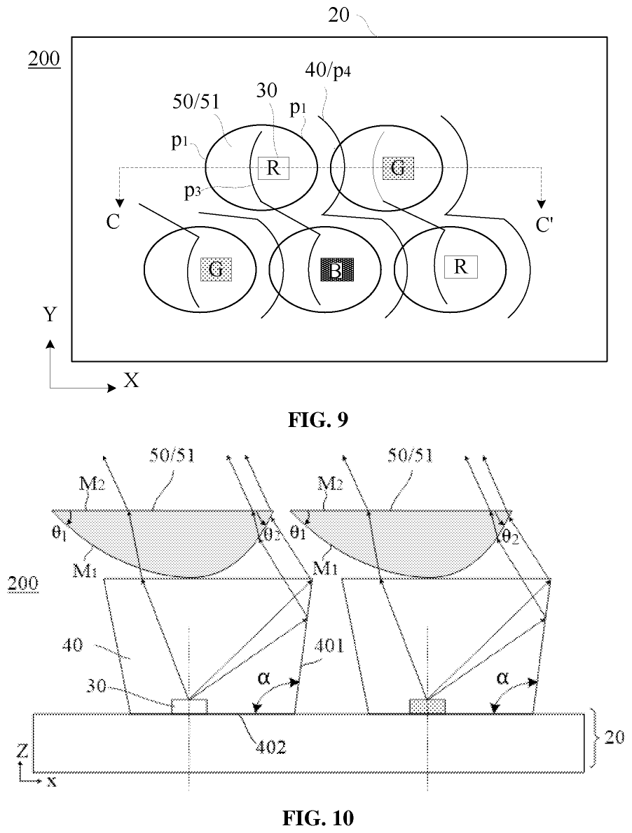

FIG. 9 is a schematic view of another display panel according to an embodiment of the present application. FIG. 10 is a sectional view of the display panel in FIG. 9 taken along CC′. In another embodiment of the present application, the first lens 51 may be provided for the light emitted by one light-emitting device 30. Referring to FIGS. 9 and 10, the orthographic projection of the first lens 51 on the driving substrate 20 covers one light-emitting device 30. Along the thickness direction Z of the display panel 200, the center of the first lens 51 does not coincide with the center of the light-emitting device 30.

For example, referring to FIG. 9, the shape of the orthographic projection of the first lens 51 on the driving substrate 20 is circular or elliptical. The center of the orthographic projection of the first lens 51 on the driving substrate 20 does not coincide with the center of the orthographic projection of the light-emitting surface of the light-emitting device 30 on the driving substrate 20. In this manner, the first lens 51 can deflect the light emitted by the light-emitting device 30 toward an oblique viewing angle.

It is to be noted that the optical relationships defined for the first lens 51 and the second lens 52 in the preceding embodiments are also applicable to the embodiment of the present application. For example, the relationship between the first base angle θ₁ and the second base angle θ₂ between the first surface M₁ and the second surface M₂ of the first lens 51 and the distance relationships among the first edge p₁ and the second edge p₂ of the first lens 51, the third edge p₃ and the fourth edge p₄ of the encapsulation structure 40, and the light-emitting device 30 are also applicable in the embodiment of the present application, and the details are not repeated.

In the present application, through the precise micro-optical process, independent fabrication and alignment of the first lens 51 are performed for one light-emitting device 30. This lens enables precise regulation of the optical path of the light-emitting device 30, causing the light to be deflected and emitted in a preset direction. In this manner, the light emission angle and the light propagation path can be controlled independently. Moreover, light at a large viewing angle is converged toward the deflection direction through the reverse chamfer of the encapsulation structure 40, thereby enhancing the overall optical performance, increasing the brightness of the display panel, mitigating color shift, and ultimately improving the visual experience of the user.

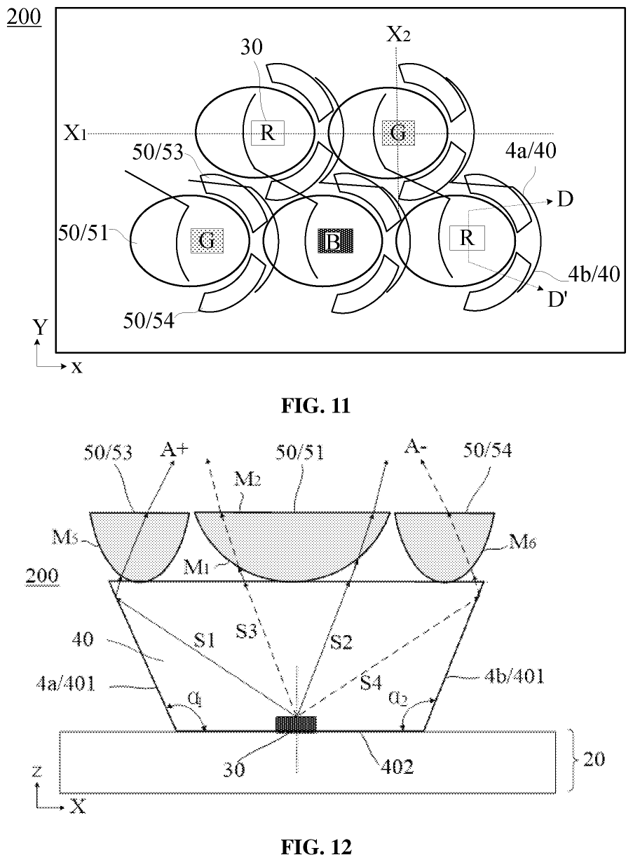

FIG. 11 is a schematic view of another display panel according to an embodiment of the present application. FIG. 12 is a sectional view of the display panel in FIG. 11 taken along DD′. Based on the preceding embodiments, with continued reference to FIGS. 11 and 12, the orthographic projection of the first lens 51 on the driving substrate 20 covers one light-emitting device 30. The lens structure 50 further includes a third lens 53 and a fourth lens 54. The third lens 53 and the fourth lens 54 each surround a portion of the first lens 51. For example, the orthographic projection of each of the third lens 53 and the fourth lens 54 on the substrate 20 is strip-shaped and partially surrounds the first lens 51.

Referring to FIG. 12, along the first direction X, the side surfaces 401 of the encapsulation structure 40 include a first side surface 4a and a second side surface 4b. The included angle between the first side surface 4a and the bottom surface 402 is a first included angle α₁, and the included angle between the second side surface 4b and the bottom surface 402 is a second included angle α₂. For example, the first side surface 4a and the second side surface 4b may be two continuous regions of the side surfaces 401.

Referring to FIG. 12, the third lens 53 includes a fifth surface M₅ facing the encapsulation structure 40. The fifth surface M₅ protrudes toward the light-emitting device 30 and faces the first included angle α₁. The fourth lens 54 includes a sixth surface M₆ facing the encapsulation structure 40. The sixth surface M₆ protrudes toward the light-emitting device 30 and faces the second included angle α₂. In one or more embodiments, with this structural design, the first part S1 of light emitted by the light-emitting device 30 is reflected by the first side surface 4a to the third lens 53, converged, and then emitted along the A+ direction. The second part S2 of light is converged by the first lens 51 and then emitted along the A+ direction. The third part S3 of light is converged by the first lens 51 and then emitted along the A− direction. The fourth part S4 of light is reflected by the second side surface 4b to the fourth lens 54, converged, and then emitted along the A− direction. In this manner, light can be converged along two directions, that is, the A+ direction and the A− direction.

Light converging along two directions refers to light emitted by the light-emitting device on a two-dimensional plane being converged along different directions. The A+ direction may be the positive direction of the X direction in the XZ plane in FIG. 12, and the A− direction may be the negative direction of the X direction in the XZ plane in FIG. 12. Alternatively, the A+ direction may be the positive direction of the Y direction in the XY plane in FIG. 12, and the A− direction may be the negative direction of the Y direction in the XY plane in FIG. 12. In the embodiment of the present application, the A+ direction and the A− direction are not limited, and the A+ direction and the A− direction are different.

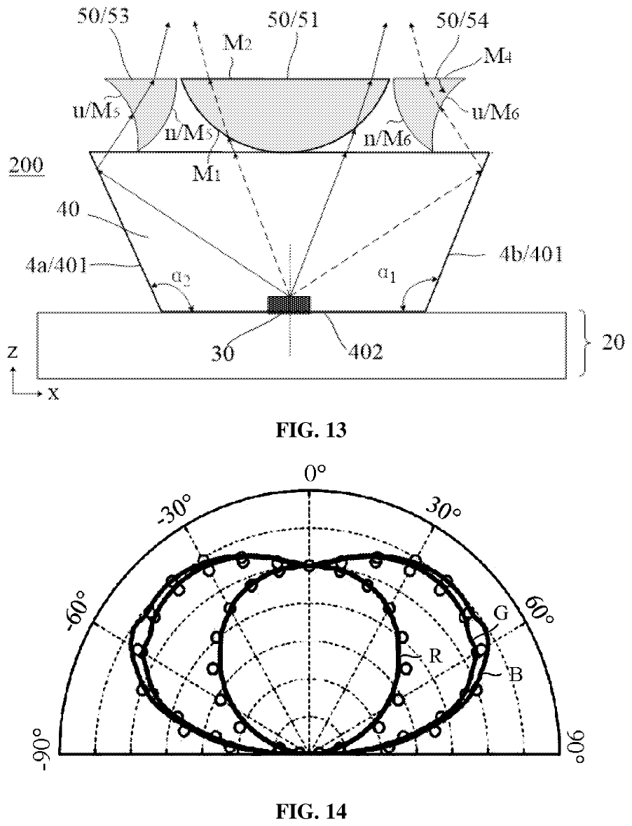

FIG. 13 is another sectional view of the display panel in FIG. 11 taken along DD′. In another embodiment of the present application, referring to FIG. 13, the third lens 53 and the fourth lens 54 may adopt the structural design of the second lens 51 shown in FIG. 7. The fifth surface M₅ of the third lens 53 and the sixth surface M₆ of the fourth lens 54 are each formed by a convex surface n and a concave surface u, thereby converging and deflecting light at a large viewing angle.

To sum up, in the embodiment of the present application, the surface profiles and light-converging directions of the third lens 53 and the fourth lens 54 are reasonably adjusted according to the display requirements of the display panel at two oblique directions, thereby converging and deflecting light emitted by the light-emitting device 30 in different directions at large viewing angles and improving the light emission efficiency of the light source at two oblique directions.

In one or more embodiments, referring to FIG. 12, the first included angle α₁ is equal to the second included angle α₂. In the embodiment of the present application, the side surface 401 of the encapsulation structure 40 is a slanted surface, and all the reverse chamfers of the slanted surface are basically uniform. This design enables the light emitted by the light-emitting device 30 to be reflected more uniformly. For example, the first included angle α₁ and the second included angle α₂ each have a range of 90° to 120°. For example, α₁ and α₂ may both be 100°. If the first included angle α₁ and the second included angle α₂ are less than 90°, the side surface 401 of the encapsulation structure 40 reflects the light at a large viewing angle toward a larger light emission angle, failing to achieve light emission at a preset oblique angle. If the first included angle α₁ and the second included angle α₂ are greater than 120°, the side surface 401 of the encapsulation structure 40 cannot collect light at a large viewing angle. In the present application, the first included angle α₁ and the second included angle α₂ are limited within the preceding range so that light at a large viewing angle can be reflected toward a preset oblique viewing angle and collected.

Based on the preceding embodiments, referring to FIGS. 11 to 13, along the thickness direction Z of the display panel, the third lens 53 and the fourth lens 54 both at least partially overlap the encapsulation structure 40. This design allows light reflected by the side surface 401 of the encapsulation structure 40 to be effectively collected and converged by the third lens 53 and the fourth lens 54.

Based on the preceding embodiments, referring to FIG. 11, the light-emitting device 30 includes a first virtual axis X₁, and the first virtual axis X₁ overlaps the center of the light-emitting device 30 and extends along the first direction X. The third lens 53 and the fourth lens 54 are symmetrical about the first virtual axis X₁. In the embodiment of the present application, through this design, the third lens 53 and the fourth lens 54 can symmetrically deflect and converge light in the A+ direction and the A− direction, respectively, thereby effectively converging light in two directions.

Based on the preceding embodiments, with continued reference to FIG. 11, the light-emitting device 30 further includes a second virtual axis X₂, and the second virtual axis X₂ overlaps the center of the light-emitting device 30 and extends along the second direction Y. The third lens 53 and the fourth lens 54 are located on the same side of the second virtual axis X₂. This configuration facilitates the third lens 53 and the fourth lens 54 in deflecting and converging the converged light along two opposite directions of the first virtual axis X₁.

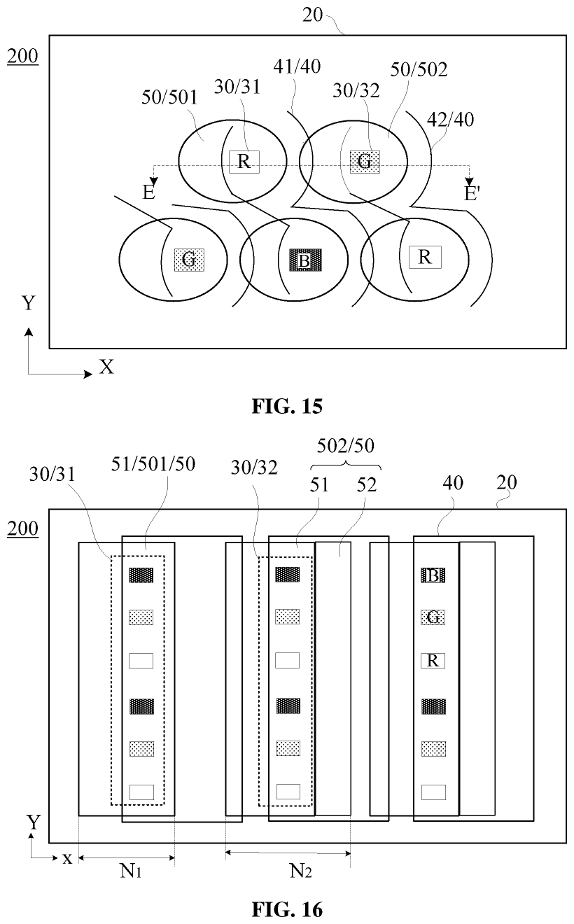

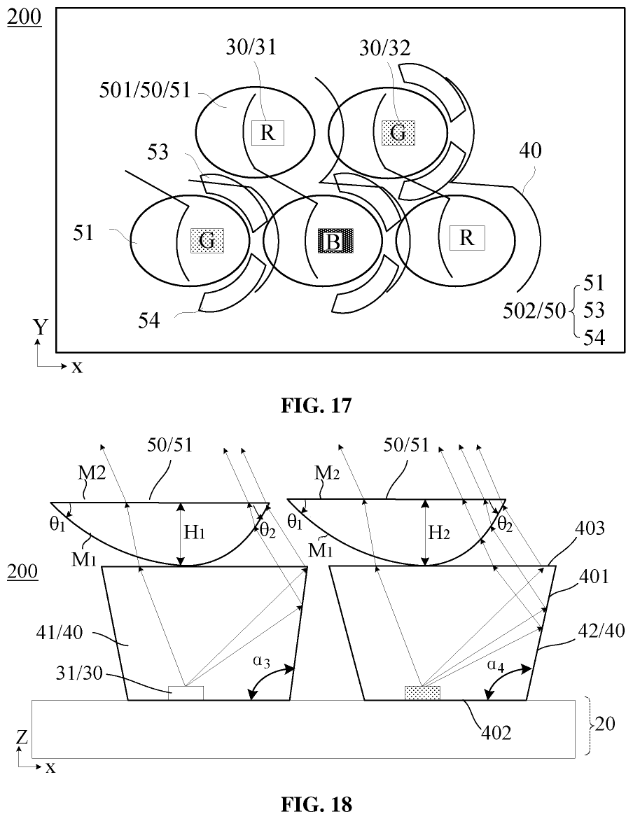

FIG. 15 is a schematic view of another display panel according to an embodiment of the present application. FIG. 16 is a schematic view of another display panel according to an embodiment of the present application. FIG. 17 is a schematic view of another display panel according to an embodiment of the present application. Based on the preceding embodiments, with continued reference to FIGS. 15 to 17, the light-emitting devices 30 include a first light-emitting device 31 and a second light-emitting device 32. The brightness of the first light-emitting device 31 at a first viewing angle is less than the brightness of the second light-emitting device 32 at the first viewing angle. The lens structures 50 include a first lens structure 501 and a second lens structure 502. Along the thickness direction Z of the display panel, the first lens structure 501 and the first light-emitting device 31 at least partially overlap, and the second lens structure 502 and the second light-emitting device 32 at least partially overlap.

The first viewing angle refers to the angular range in which the detector collects or the user observes the light-emitting surface of the light-emitting device. For example, the included angle range between the light and the normal to the light-emitting surface within this angular range is 30° to 90°. It is to be noted that the first viewing angle is a reference angle that is reasonably set based on display requirements and is not specifically limited in the embodiment of the present application.

In some examples, referring to FIG. 15, the first light-emitting device 31 and the second light-emitting device 32 are light-emitting devices with different light emission colors. For example, the first light-emitting device 31 is a red light-emitting device R, and the second light-emitting device 32 is a green light-emitting device G or a blue light-emitting device B. Due to the light emission characteristics of the luminous materials of the light-emitting devices 30 and the light refraction characteristics of the lens refractive index, the first light-emitting device 31 and the second light-emitting device 32 with different light emission colors have different brightness when viewed from the same viewing angle (the first viewing angle). For example, referring to FIG. 14, the brightness of each of the green light-emitting device G and the blue light-emitting device B at a large viewing angle is greater than the brightness of the red light-emitting device R at a large viewing angle when the viewing angle is from 0° to 90° and from 0° to −90 °. In other words, the light leakage of each of the green light-emitting device G and the blue light-emitting device B at a large viewing angle is greater than the light leakage of the red light-emitting device R at a large viewing angle. Based on this, in the present application, the brightness at a preset oblique viewing angle can be increased by adjusting the optical path structure corresponding to the light-emitting device with more light leakage at a large viewing angle.

In some examples, referring to FIG. 16, the first light-emitting device 31 may refer to the combination of all light-emitting devices in the first column, and the second light-emitting device 32 may refer to the combination of all light-emitting devices in the second column. When the light-emitting devices in different columns are observed from the same viewing angle (the first viewing angle), the light-emitting devices in two columns have different brightness.

In the present application, for the light-emitting devices with different brightness at the same viewing angle, the differentiated design is performed on at least one parameter of the corresponding lens structure 50, such as the curved surface profile, the refractive index, and the width, such that the brightness of different light-emitting devices at a preset oblique viewing angle is consistent.

In one or more embodiments, the first lens structure 501 and the second lens structure 502 differ in the curvature of the first surface; and/or the first lens structure 501 and the second lens structure 502 differ in refractive index; and/or the first lens structure 501 and the second lens structure 502 differ in width along the first direction X. The first direction X is parallel to the plane where the driving substrate 20 is located.

In one or more embodiments, the first lens structure 501 and the second lens structure 502 differ in the curvature of the first surface facing the light-emitting device 30, resulting in different light converging effects of the first lens structure 501 and the second lens structure 502 for light at the same angle. The first lens structure 501 and the second lens structure 502 have different refractive indices, resulting in different light converging effects of the first lens structure 501 and the second lens structure 502 for light at the same angle. The first lens structure 501 and the second lens structure 502 differ in width in the X direction in the plane parallel to the driving substrate 20, resulting in different light converging effects of the first lens structure 501 and the second lens structure 502 for light at the same angle. Therefore, the first lens structure 501 and the second lens structure 502 differ in at least one of curvature, refractive index, and width in the X direction in the plane parallel to the driving substrate 20 so that the leaked light at a large viewing angle can be collected, the amounts of light emitted by the first light-emitting device 31 and the second light-emitting device 32 at oblique angles can be balanced, and color shift in the display panel can be avoided.

Based on the preceding embodiments, referring to FIGS. 16 and 17, the number of lenses in the first lens structure 501 is less than the number of lenses in the second lens structure 502. In the embodiment of the present application, for the first light-emitting device 31 with less light leakage at a large viewing angle (the same viewing angle), the number of corresponding lenses collecting light at large viewing angles can be reduced or corresponding lenses collecting light at large viewing angles can be removed, thereby balancing the consistency of the light emission angle distribution of the light-emitting device, reducing the fabrication cost, and improving the lens fabrication process.

For example, referring to FIG. 16, at the same oblique viewing angle, the brightness of the first light-emitting device 31 is lower than the brightness of the second light-emitting device 32, the first lens structure 501 corresponding to the first light-emitting device 31 includes one first lens 51, and the second lens structure 502 corresponding to the second light-emitting device 32 includes one first lens 51 and one second lens 52. The second lens 52 is disposed at a position corresponding to the second light-emitting device 32, and the second lens 52 converges the leaked light from the second light-emitting device 32 at a large viewing angle so that the first light-emitting device 31 and the second light-emitting device 32 are consistent in the brightness at the preset oblique viewing angle.

For example, referring to FIG. 17, the first light-emitting device 31 is a red light-emitting device R, and the corresponding first lens structure 501 includes one first lens 51. The second light-emitting device 32 is a green light-emitting device G or a blue light-emitting device B, and the corresponding second lens structure 502 includes one first lens 51, one third lens 53, and one fourth lens 54. The third lens 53 and the fourth lens 54 converge the leaked light from the second light-emitting device 32 at large viewing angles so that the first light-emitting device 31 and the second light-emitting device 32 are consistent in the brightness at two preset oblique viewing angles.

Based on the preceding embodiments, referring to FIG. 16, along the first direction X, the width N₁ of the first lens structure 501 is less than the width N₂ of the second lens structure 502, that is, N₁<N₂. In the embodiment of the present application, by increasing the width N₂ of the second lens structure 502, more leaked light from the second light-emitting device 32 at large viewing angles is converged so that the first light-emitting device 31 and the second light-emitting device 32 are consistent in the brightness at the preset oblique viewing angle.

FIG. 18 is a sectional view of the display panel in FIG. 15 taken along EE′. Based on the preceding embodiments, referring to FIG. 18, the encapsulation structures 40 include a first encapsulation structure 41 and a second encapsulation structure 42, the first encapsulation structure 41 covers the light-emitting surface of the first light-emitting device 31, and the second encapsulation structure 42 covers the light-emitting surface of the second light-emitting device 32. The included angle α₃ between the side surface and the bottom surface of the first encapsulation structure 41 is less than the included angle α₄ between the side surface and the bottom surface of the second encapsulation structure 42, where α₃<α₄. In the embodiment of the present application, by increasing the reverse chamfer of the second encapsulation structure 42, the oblique side surface of the second light-emitting device 32 reflects more leaked light at large viewing angles to the second lens structure 502 so that the light emission brightness consistency of the first light-emitting device 31 and the second light-emitting device 32 at the preset oblique viewing angle is improved.

Based on the preceding embodiments, referring to FIG. 18, along the thickness direction Z of the display panel 200, the thickness H₁ of the first lens structure 501 is less than the thickness H₂ of the second lens structure 502. In the embodiment of the present application, the thickness H₁ of the first lens structure 501 may be appropriately reduced to improve the precision of the imprinting process for the first lens structure 501 and enhance the light converging capability so that the light emission brightness consistency of the first light-emitting device 31 and the second light-emitting device 32 at the preset oblique angle is balanced.

Based on the preceding embodiments, referring to FIG. 18, the encapsulation structure 40 further includes a top surface 403, and the area of the top surface 403 is greater than the area of the bottom surface 402. For example, the encapsulation structure 40 is an inverted trapezoidal structure. This structural design facilitates the convergence of light reflected from the side surface 401 to the lens structure 50.

In FIGS. 2 to 17, the top surface of the encapsulation structure 40 is not shown. The top surface in FIG. 18 is used as an example for illustration.

Based on the preceding embodiments, referring to FIGS. 2 to 18, the display panel 200 further includes a filler layer (not shown in the figures) disposed between adjacent encapsulation structures 40, and the refractive index of the filler layer is less than the refractive index of the encapsulation structure 40.

For example, the gap between adjacent encapsulation structures 40 may be in a vacuum state. The extremely low refractive index is conducive to achieving the total reflection of light at a large viewing angle on the side surface 401 of the encapsulation structure 40, thereby guiding light to the lens structure 50 and effectively enhancing the reflection effect of the reverse chamfer structure on light at a large viewing angle. Alternatively, the gap may be filled with a transparent material with a lower refractive index, such as an optical adhesive. When light at a large viewing angle reaches the interface at a larger angle of incidence, higher reflectivity can still be maintained; while when the angle of incidence is smaller, more light is transmitted through the interface, which is conducive to regulating the light field distribution at different viewing angles.

In addition, to further improve optical performance, a reflective layer may be disposed on the side surface 401 of the encapsulation structure 40. The reflective layer can significantly increase the reflection efficiency for light at a large viewing angle so that it is ensured that more light is used effectively, thereby optimizing the overall brightness and viewing angle performance of the display panel.

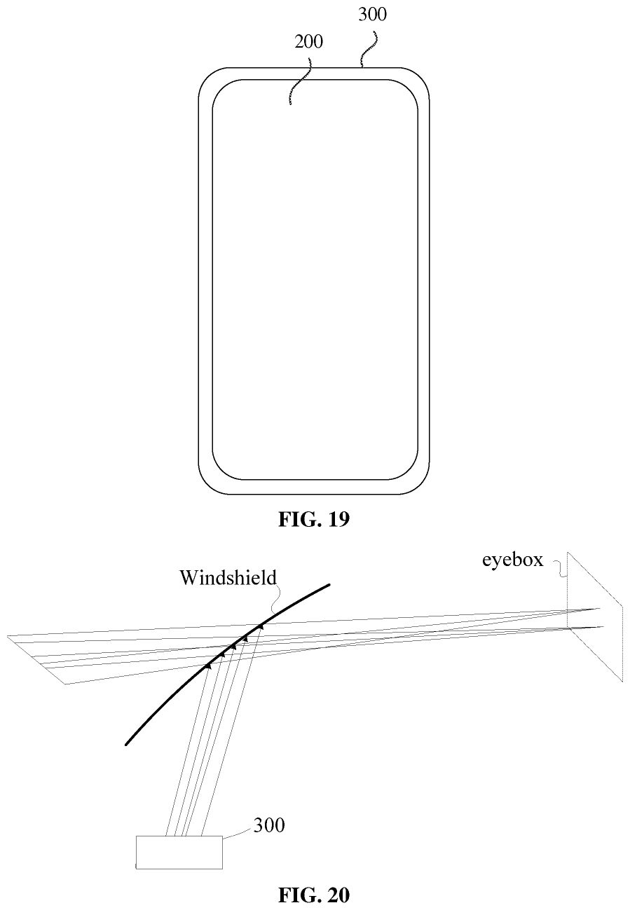

Based on the same inventive concept, embodiments of the present disclosure further provide a display device. FIG. 19 is a structural view of a display device according to an embodiment of the present disclosure. FIG. 20 is a schematic view of the structure of a display device applied to an HUD according to an embodiment of the present disclosure. As shown in FIGS. 19 and 20, a display device 300 includes any display panel 200 provided in the preceding embodiments. Therefore, the display device 300 also has the beneficial effects of the display panel 200 in the preceding embodiments. For the same details, reference may be made to the preceding description of the display panel 200, and the details are not repeated below.

The display device 300 provided in the embodiment of the present disclosure may be an in-vehicle display shown in FIG. 19 and may be applied to the HUD display shown in FIG. 20. The display device 300 may also be any electronic product with a display function, including, but not limited to, a television, a laptop, a desktop display, a tablet computer, a digital camera, a smart bracelet, smart glasses, an in-vehicle display, industry-controlling equipment, a medical display screen, or a touch interactive terminal, which is not specifically limited in the embodiment of the present disclosure.

It is to be noted that the preceding are preferred embodiments of the present disclosure and technical principles used therein. It is to be understood by those skilled in the art that the present disclosure is not limited to the specific embodiments described herein, and the features of the embodiments of the present disclosure may be partially or wholly coupled or combined with one another, may cooperate with each other in various manners, and may be technically driven. Those skilled in the art can make various apparent modifications, adaptations, combinations, and substitutions without departing from the scope of the present disclosure. Therefore, while the present disclosure is described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A display panel, comprising:
a driving substrate;
a light-emitting device electrically connected to one side of the driving substrate;
an encapsulation structure, wherein the encapsulation structure covers a light-emitting surface of the light-emitting device, the encapsulation structure comprises a side surface and a bottom surface, and an included angle between the side surface and the bottom surface is an obtuse angle; and
a lens structure, wherein the lens structure is located on one side of the encapsulation structure facing away from the light-emitting device, the lens structure comprises a first lens, and the first lens comprises a first surface facing the encapsulation structure and protruding toward the light-emitting device;
wherein along a thickness direction of the display panel, the light-emitting device, the first lens, and the encapsulation structure at least partially overlap.

2. The display panel of claim 1, wherein
the first lens comprises a first edge and a second edge, and the first edge and the second edge are arranged along a first direction and extend along a second direction, wherein the first direction and the second direction intersect and are both parallel to a plane where the driving substrate is located;
the encapsulation structure corresponding to the first lens comprises a third edge and a fourth edge, and the third edge and the fourth edge are arranged along the first direction and extend along the second direction; and
along the first direction, a distance between the first edge and the light-emitting device is greater than a distance between the second edge and the light-emitting device, and a distance between the third edge and the light-emitting device is less than a distance between the fourth edge and the light-emitting device.

3. The display panel of claim 2, wherein the first lens further comprises a second surface facing away from the encapsulation structure; and
along the first direction, included angles between the first surface and the second surface comprise a first base angle and a second base angle, wherein the first base angle and the second base angle are different.

4. The display panel of claim 2, comprising a plurality of light-emitting devices arranged in an array, wherein a distance between two adjacent light-emitting devices arranged in the first direction is greater than a distance between two adjacent light-emitting devices arranged in the second direction; and
an orthographic projection of the first lens on the driving substrate covers a plurality of light-emitting devices arranged along the second direction;
wherein along the first direction, light emission colors of a plurality of light-emitting devices are the same; and
along the second direction, at least two of a plurality of light-emitting devices covered by the orthographic projection of a same first lens emit different colors.

5. The display panel of claim 2, wherein an orthographic projection of the first lens on the driving substrate covers one light-emitting device;
wherein along the thickness direction of the display panel, a center of the first lens does not coincide with a center of the light-emitting device.

6. The display panel of claim 1, wherein the lens structure further comprises a second lens, and the second lens is located between two adjacent first lenses and at least partially surrounds the first lens; and
along the thickness direction of the display panel, the second lens and the encapsulation structure at least partially overlap.

7. The display panel of claim 6, wherein the second lens comprises a third surface facing the encapsulation structure, and the third surface comprises a convex surface and a concave surface connected to each other; and
the convex surface is located on one side of the concave surface facing the first lens and protrudes toward the first lens, and the concave surface is recessed toward the included angle between the side surface and the bottom surface.

8. The display panel of claim 6, wherein
the second lens comprises a third surface facing the encapsulation structure and a fourth surface facing away from the encapsulation structure, and the third surface protrudes toward the light-emitting device; and
along a first direction, included angles between the third surface and the fourth surface comprise a third base angle and a fourth base angle, and the third base angle and the fourth base angle are different, wherein the first direction is parallel to a plane where the driving substrate is located.

9. The display panel of claim 8, wherein
the first lens further comprises a second surface facing away from the encapsulation structure; and along the first direction, included angles between the first surface and the second surface comprise a first base angle and a second base angle;
wherein the third base angle is less than or equal to the first base angle, and the fourth base angle is less than or equal to the second base angle.

10. The display panel of claim 9, wherein the first base angle is less than or equal to the second base angle, and the third base angle is less than or equal to the fourth base angle.

11. The display panel of claim 6, wherein the display panel satisfies at least one of the following:
along a first direction, a width of the first lens is greater than a width of the second lens, and the first direction is parallel to a plane where the driving substrate is located; or
along the thickness direction of the display panel, a thickness of the first lens is the same as a thickness of the second lens.

12. The display panel of claim 5, wherein
the lens structure further comprises a third lens and a fourth lens;
the third lens and the fourth lens each surround a portion of the first lens;
along the first direction, the side surface of the encapsulation structure comprises a first side surface and a second side surface, an included angle between the first side surface and the bottom surface is a first included angle, and an included angle between the second side surface and the bottom surface is a second included angle;
the third lens comprises a fifth surface facing the encapsulation structure, and the fifth surface protrudes toward the light-emitting device and faces the first included angle; and
the fourth lens comprises a sixth surface facing the encapsulation structure, and the sixth surface protrudes toward the light-emitting device and faces the second included angle.

13. The display panel of claim 12, wherein the display panel satisfies at least one of the following:
the first included angle is equal to the second included angle; or
the first included angle and the second included angle each have a range of 90° to 120°.

14. The display panel of claim 12, wherein
along the thickness direction of the display panel, the third lens and the fourth lens both at least partially overlap the encapsulation structure.

15. The display panel of claim 12, wherein the light-emitting device comprises a first virtual axis, and the first virtual axis overlaps the center of the light-emitting device and extends along the first direction; and
the third lens and the fourth lens are symmetrical about the first virtual axis.

16. The display panel of claim 15, wherein
the light-emitting device further comprises a second virtual axis, and the second virtual axis overlaps the center of the light-emitting device and extends along the second direction; and
the third lens and the fourth lens are located on a same side of the second virtual axis.

17. The display panel of claim 2, wherein
the light-emitting device comprises a first light-emitting device and a second light-emitting device, and brightness of the first light-emitting device at a first viewing angle is less than brightness of the second light-emitting device at the first viewing angle;
the lens structure comprises a first lens structure and a second lens structure; and along the thickness direction of the display panel, the first lens structure and the first light-emitting device at least partially overlap, and the second lens structure and the second light-emitting device at least partially overlap;
the first lens structure and the second lens structure differ in curvature of the first surface; and/or
the first lens structure and the second lens structure differ in refractive index; and/or
the first lens structure and the second lens structure differ in width along the first direction;
wherein the first direction is parallel to the plane where the driving substrate is located.

18. The display panel of claim 17, wherein the display panel satisfies at least one of the following:
a number of lenses in the first lens structure is less than a number of lenses in the second lens structure;
along the first direction, a width of the first lens structure is less than a width of the second lens structure;
the encapsulation structures comprise a first encapsulation structure and a second encapsulation structure, the first encapsulation structure covers a light-emitting surface of the first light-emitting device, the second encapsulation structure covers a light-emitting surface of the second light-emitting device, and an included angle between a side surface and a bottom surface of the first encapsulation structure is less than an included angle between a side surface and a bottom surface of the second encapsulation structure;
or
along the thickness direction of the display panel, a thickness of the first lens structure is less than a thickness of the second lens structure.

19. The display panel of claim 1, wherein the encapsulation structure further comprises a top surface, and an area of the top surface is greater than an area of the bottom surface.

20. A display device, comprising a display panel, wherein the display panel comprises:
a driving substrate;
a light-emitting device electrically connected to one side of the driving substrate;
an encapsulation structure, wherein the encapsulation structure covers a light-emitting surface of the light-emitting device, the encapsulation structure comprises a side surface and a bottom surface, and an included angle between the side surface and the bottom surface is an obtuse angle; and
a lens structure, wherein the lens structure is located on one side of the encapsulation structure facing away from the light-emitting device, the lens structure comprises a first lens, and the first lens comprises a first surface facing the encapsulation structure and protruding toward the light-emitting device;
wherein along a thickness direction of the display panel, the light-emitting device, the first lens, and the encapsulation structure at least partially overlap.
